(19) United States
(12) Patent Application Publication
(10) Pub. No.: US 2026/0170193 A1
(43) Pub. Date: Jun. 18, 2026

(54) INTERACTIVE SHIP DESIGN SYSTEM AND METHOD USING CONVERSATIONAL ARTIFICIAL INTELLIGENCE MODEL

(71) Applicant: INSTITUTE FOR ADVANCED ENGINEERING, Yongin-si Gyeonggi-do (KR)

(72) Inventors: Sangjoon YOON, Suwon-si Gyeonggi-do (KR); Joonghyeok LEE, Seoul (KR); Jaehoon SON, Goyang-si Gyeonggi-do (KR); Jungeun AN, Seongnam-si Gyeonggi-do (KR)

(73) Assignee: INSTITUTE FOR ADVANCED ENGINEERING, Yongin-si Gyeonggi-do (KR)

(21) Appl. No.: 19/395,317

(22) Filed: Nov. 20, 2025

(30) Foreign Application Priority Data
Dec. 18, 2024 (KR) 10-2024-0190438

(51) Int. Cl. G06F 30/15; G06F 30/27

(52) U.S. Cl. CPC G06F 30/15; G06F 30/27

(57) ABSTRACT

An automatic ship design system and method using a conversational artificial intelligence model are disclosed. According to an embodiment of the present invention, the automatic ship design system using a conversational artificial intelligence model includes a memory in which one or more instructions, ship design knowledge information, and the conversational artificial intelligence model are stored; a communication unit for communication with a user terminal; and a processor configured to communicate with the user terminal via the communication unit and execute the one or more instructions stored in the memory, wherein the processor is configured to perform a conversation with the user through the user terminal by using the conversational artificial intelligence model, receive ship design variables through the conversation, and derive ship design information in real time using the ship design knowledge information according to the received ship design variables.

### CROSS-REFERENCE TO RELATED APPLICATION

This application claims priority to and the benefit of Korean Patent Application No. 10-2024-0190438, filed on December 18, 2024, the disclosure of which is incorporated herein by reference in its entirety.

### BACKGROUND

### 1. Field of the Invention

The present invention relates to an automatic ship design system and method using a conversational artificial intelligence model. More specifically, the present invention relates to a system and method of collecting information required for ship design through a conversation with a user and automatically performing ship design based on the collected information.

### 2. Discussion of Related Art

Ship design work is work that is complex and requires a lot of time and effort. A design engineer needs to analyze a shipowner’s requirements and derive an optimal design plan in consideration of various design variables. In this process, a lot of expertise and experience have been required, and design change and modification work has also occurred frequently. Accordingly, a problem has arisen in that work efficiency has decreased.

### SUMMARY OF THE INVENTION

The present invention has been made to solve the above-described problems, and the present invention is directed to an automatic ship design system and method using a conversational artificial intelligence model, which can improve the efficiency of ship design work by receiving design variables of a ship using a conversational artificial intelligence model and deriving ship design information reflecting the received design variables in real time.

The present invention is also directed to an automatic ship design system and method using a conversational artificial intelligence model, which can automatically derive a design plan of a target design ship that is a user’s conversational intent by predicting the target design ship and generating questions regarding related design variables step by step and asking the questions to the user to complete the target design ship, and which enables even a technician lacking expertise to easily obtain a high-quality design result.

The present invention is also directed to an automatic ship design system and method using a conversational artificial intelligence model, which can increase user convenience so that anyone can easily perform ship design through a conversational interface and which enables the design to be performed intuitively.

The problems to be solved by the present invention are not limited to the content mentioned above, and other technical problems that are not mentioned will be clearly understood by those of ordinary skill in the art from the following description.

According to an aspect of the present invention, there is provided an automatic ship design system using a conversational artificial intelligence model, including a memory in which one or more instructions, the conversational artificial intelligence model, and ship design knowledge information are stored, a communication unit for communication with a user terminal, and a processor configured to communicate with the user terminal via the communication unit and execute the one or more instructions stored in the memory, wherein the processor is configured to perform a conversation with the user through the user terminal by using the conversational artificial intelligence model, receive ship design variables through the conversation, and derive ship design information in real time using the ship design knowledge information according to the received ship design variables.

Further, the ship design knowledge information may include one or more of ship design requirement information, ship type and ship size information, definition information of a design stage, and boundary range information of the design stage.

Further, the ship design information may include one or more of ship shape information, ship design drawings, and an estimated ship design cost.

Further, the processor may sequentially generate questions for ascertaining the user’s intent based on the ship design knowledge information by using the conversational artificial intelligence model, and sequentially provide the generated questions to the user through the user terminal.

Further, the processor may sequentially receive answers to the questions from the user terminal and determine the user’s intent based on the received answers to reflect the user’s intent in the ship design information.

Further, the processor may update the ship design information in real time based on the ship design variables included in the answers.

Further, the user’s intent may be a target design ship that the user desires to design, and the processor may predict the target design ship and sequentially generate questions for the ship design variables for specifically designing the predicted target design ship.

According to another aspect of the present invention, there is provided a method performed by a processor of an automatic ship design system using a conversational artificial intelligence model, the method including performing a conversation with a user through a user terminal using the conversational artificial intelligence model, receiving ship design variables through the conversation, and deriving ship design information in real time using the ship design knowledge information according to the received ship design variables.

Further, the performing of the conversation with the user through the user terminal may include sequentially generating questions for ascertaining the user’s intent based on the ship design knowledge information by using the conversational artificial intelligence model, and sequentially providing the generated questions to the user through the user terminal.

Further, the deriving of the ship design information may include determining the user’s intent based on the answers to the questions received from the user terminal and reflecting the user’s intent in the ship design information.

Further, the deriving of the ship design information may include updating the ship design information in real time based on the ship design variables included in the answers.

Further, the user’s intent may be a target design ship that the user desires to design, and the sequentially generating of the questions may include predicting the target design ship and sequentially generating questions for the ship design variables for specifically designing the predicted target design ship.

### BRIEF DESCRIPTION OF THE DRAWINGS

The above and other objects, features and advantages of the present invention will become more apparent to those of ordinary skill in the art by describing exemplary embodiments thereof in detail with reference to the accompanying drawings, in which:

FIG. 1 is a block diagram illustrating an automatic ship design system using a conversational artificial intelligence model according to an embodiment of the present invention;

FIG. 2 is a block diagram illustrating a structure of data stored in a memory according to an embodiment of the present invention;

FIG. 3 is a flowchart illustrating a method performed by a processor of the automatic ship design system using a conversational artificial intelligence model according to the embodiment of the present invention;

FIG. 4 is a flowchart illustrating a specific method of one step of FIG. 3;

FIG. 5 is a diagram illustrating a conversational interface according to an embodiment of the present invention; and

FIG. 6 is a diagram illustrating design variables received through the conversational interface, and an estimated ship design cost and a ship shape derived according to the design variables according to an embodiment of the present invention.

### DETAILED DESCRIPTION OF EXEMPLARY EMBODIMENTS

Hereinafter, embodiments of the present invention will be described in detail with reference to the accompanying drawings so that those of ordinary skill in the art to which the present invention pertains can easily carry out the invention. However, the present invention may be implemented in various different forms and is not limited to the embodiments that will be described herein. In the drawings, parts not related to the description are omitted in order to clearly describe embodiments of the present invention.

The terms used in the present specification are merely used to describe specific embodiments and are not intended to limit the present invention. The singular expressions may include plural expressions unless clearly indicated otherwise in the context.

In the present specification, terms such as “include,” “have,” or “comprise” are intended to designate that there are features, numbers, steps, operations, components, parts, or combinations thereof in the specification, and are to be understood as not precluding the possibility that one or more other features, numbers, steps, operations, components, parts, or combinations thereof may be present or may be added.

Further, constituent parts appearing in the embodiments of the present invention are illustrated independently in order to represent different characteristic functions, and do not mean that each constituent part is configured by separate hardware or a single software configuration unit. That is, for convenience of description, each constituent part is listed and described as an individual constituent part, and at least two of the constituent parts may be combined into one constituent part, or one constituent part may be divided into a plurality of constituent parts to perform functions. An integrated embodiment and separated embodiments of the respective constituent parts are also included in the scope of the present invention as long as the embodiments do not depart from the spirit of the present invention.

Further, the following embodiments are provided to explain the present invention more clearly to those of ordinary skill in the art, and shapes and sizes of elements in the drawings may be exaggerated for clearer description.

Hereinafter, preferred embodiments of the present invention will be described with reference to the accompanying drawings.

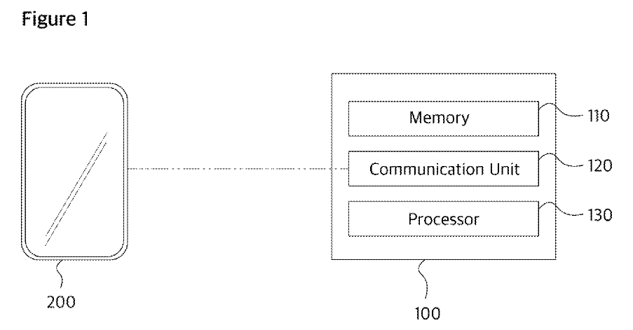

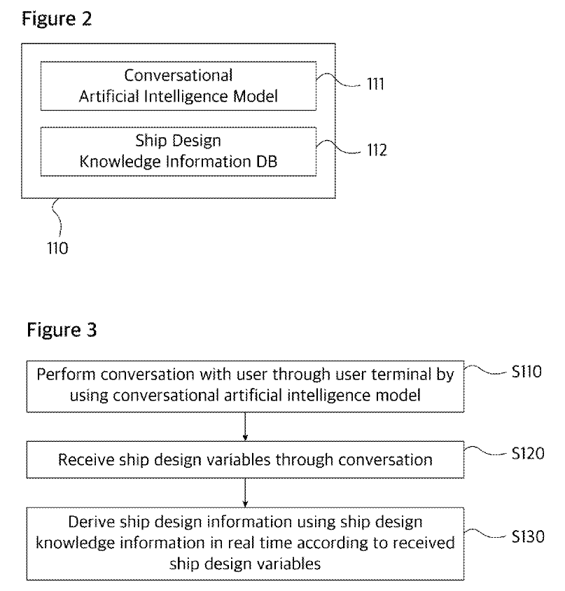

FIG. 1 is a block diagram illustrating an automatic ship design system using a conversational artificial intelligence model according to an embodiment of the present invention, and FIG. 2 is a block diagram illustrating a structure of data stored in a memory according to an embodiment of the present invention.

Referring to FIGS. 1 and 2, an automatic ship design system 100 using a conversational artificial intelligence model according to an embodiment of the present invention collects ship design variables through conversation with a user by using the conversational artificial intelligence model and automatically performs ship design based on the ship design variables, and the automatic ship design system 100 may include a memory 110, a communication unit 120, and a processor 130.

Various data and instructions for controlling an operation of respective components of the automatic ship design system 100 may be stored in the memory 110.

Ship design knowledge information may be stored in the form of a database 112 in the memory 110. The ship design knowledge information is information required for a conversational artificial intelligence model 111 to perform ship design through conversation with the user, and may be ship design requirement information, ship type and ship size information, definition information of a design stage, boundary range information of the design stage, question classification information, ship design drawings, ship design rules, ship design cases, ship operation data, ship accident cases, and the like.

The ship design requirement information is information including various requirements for ship design, such as a purpose, size, speed, cargo capacity, operational range, and safety regulations of the ship, the ship design requirement information for a container ship may include a container loading capacity, a type of crane, an accommodation ability of refrigeration containers, and the like, and the ship design requirement information for a tanker may include a type of crude oil, a cargo tank capacity, a discharge system, and the like.

The ship type and ship size information may include information on a ship type such as a bulk carrier, container ship, tanker, and LNG carrier, and a size for each ship type such as length, breadth, depth, and tonnage.

The definition information of the design stage may include information on targets, tasks, deliverables, and the like of each design stage in a ship design stage, which is classified into concept design, basic design, detailed design, and production design.

The boundary range information of the design stage may include information on a criterion for determining the start and end of each design stage in the ship design, that is, a boundary range of each stage.

The question classification information may include information for classifying a user’s question as a question corresponding to a specific ship type and ship size or a generally applied question. For example, “How should a cargo loading space of a container ship be designed?” may be a question specific to a container ship, and “What design factors should be considered to improve the safety of a ship?” may be a general question.

The memory 110 may store the conversational artificial intelligence model 111. In one embodiment, the conversational artificial intelligence model 111 is a large language model (LLM) trained on the ship design knowledge information and may classify the content of question-and-answer with the user according to the ship type and ship size, and provide answers based on this.

The communication unit 120 may communicate with an external device, such as a user terminal 200, to receive questions and provide answers.

The processor 130 may communicate with the user terminal 200 via the communication unit 120 and execute instructions stored in the memory 110 to control an operation of the automatic ship design system 100. The processor 130 may perform a natural-language-based conversation with the user via the user terminal 200 by using the conversational artificial intelligence model 111. The processor 130 may receive variables required for ship design through conversation with the user, and derive ship design information based on the received design variables and the ship design knowledge information in real time. For example, when the user accesses the automatic ship design system 100 through the user terminal 200 and inputs “I want to design a 10,000 TEU-class container ship,” the processor 130 may recognize this as ship design variables (ship type: container ship, and size: 10,000 TEU) and generate initial ship design information by utilizing the ship design knowledge information stored in the memory 110.

The ship design variables may be a ship type, length, breadth, draft, size such as class, fuel, crew, equipment number, number of crew members, cargo capacity, fuel-tank arrangement, loading/unloading device, and environmental regulations.

The ship design information is a ship design result that the processor 130 derives by reflecting the received ship design variables, and may include one or more of ship shape information, ship design drawings, and estimated ship design cost.

The ship shape information is information representing a three-dimensional shape of the ship, the processor 130 may update and display a three-dimensional ship shape in real time, and the user may intuitively check an external shape of the ship and request modifications as needed.

The ship design drawings may be drawings representing a detailed design of each part of the ship.

The estimated ship design cost is information for predicting a ship construction cost, and the processor 130 predicts the ship construction cost in real time, thereby efficiently managing a budget for each design stage.

The processor 130 may provide an optimized answer to the user in consideration of a question timing in an entire working process. The processor 130 may receive a question from the user terminal 200 through the communication unit 120 according to various data and instructions stored in the memory 110 and determine timing information of the received question. The timing information is information indicating which of all work stages the received question corresponds to, and the processor 130 may analyze the context and content of the question using the conversational artificial intelligence model 111 to determine the timing information. For example, the processor 130 may extract keywords using the conversational artificial intelligence model 111 to determine the timing information of the question.

The processor 130 analyzes the context and content of the question using the conversational artificial intelligence model 111, determines which stage in the ship design stage the content of the question corresponds to, and derives ship design drawings based on the determined design stage. For example, the processor 130 may derive basic drawings of the ship such as a general arrangement plan and a main compartment arrangement plan in a basic design stage, and derive detailed drawings for each part, such as engine room arrangement diagrams and piping system drawings in a detailed design stage.

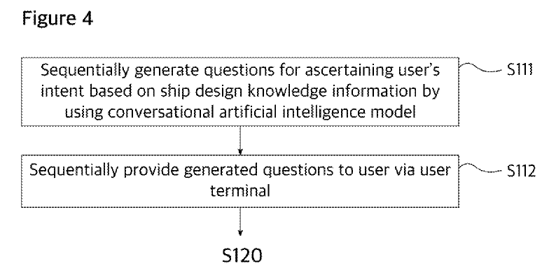

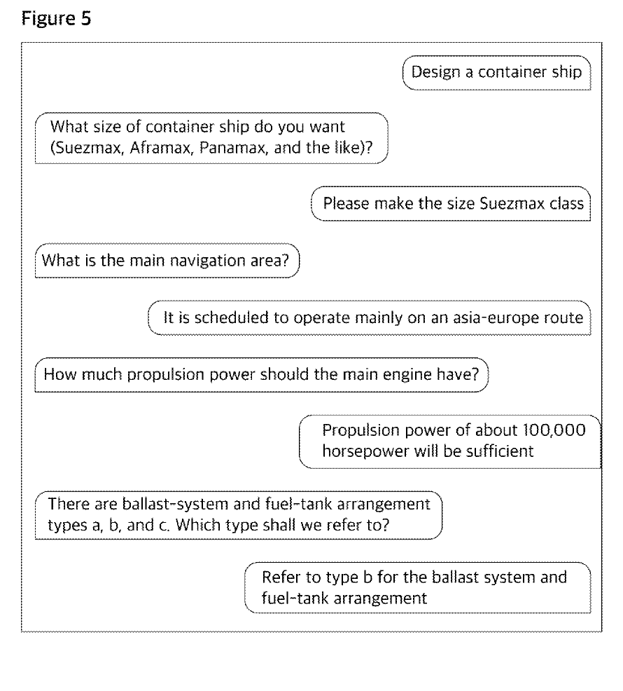

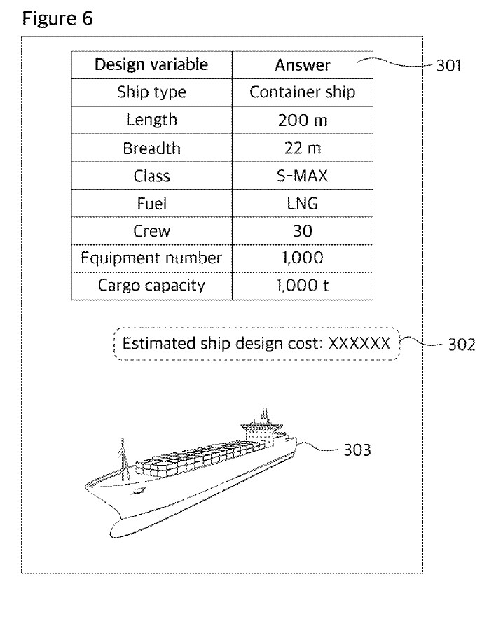

FIG. 3 is a flowchart illustrating a method performed by a processor of the automatic ship design system using a conversational artificial intelligence model according to the embodiment of the present invention, FIG. 4 is a flowchart illustrating a specific method of one step of FIG. 3, FIG. 5 is a diagram illustrating a conversational interface according to an embodiment of the present invention, and FIG. 6 is a diagram illustrating design variables received through the conversational interface and a ship shape derived according to the design variables according to an embodiment of the present invention.

An operation of the processor 130 of the automatic ship design system 100 using a conversational artificial intelligence model according to the embodiment of the present invention will be described with reference to FIGS. 1 to 6.

A user may access the automatic ship design system 100 through the user terminal 200. The processor 130 provides a conversational interface I to the user via the user terminal 200, and the user may converse with the automatic ship design system 100 through the interface I. The processor 130 may perform a conversation with the user by using the conversational artificial intelligence model 111 (S110). The user may input information on a ship to be designed, that is, ship design variables, to the automatic ship design system 100 while conversing through the interface I, and the processor 130 may extract and receive the ship design variables from the conversation input through the interface I (S120). When the ship design variables are received, the processor 130 may derive the ship design information using the ship design knowledge information in real time (S130).

In one embodiment, the operation S110 of performing conversation with the user may include an operation S111 of sequentially generating questions for ascertaining the user’s intent based on the ship design knowledge information by using the conversational artificial intelligence model 111, and an operation S112 of sequentially providing the generated questions to the user via the user terminal 200.

When the user makes a request such as “Design a container ship” on the interface I, the processor 130 may analyze the user’s utterance, that is, “Design a container ship,” by using the conversational artificial intelligence model 111 and ascertain that the user intends to design a container ship. The processor 130 may ascertain information required for container ship design based on the ship design knowledge information. For example, the processor 130 may ascertain, through the ship design knowledge information, the information required for container ship design, such as a size of the container ship, a major navigation area, engine propulsion power, a ballast system, and a fuel-tank arrangement. The processor 130 may sequentially generate questions for concretizing the user’s intent based on the ascertained information. For example, the processor 130 may sequentially generate questions such as “What size of container ship do you want? (Suezmax, Aframax, Panamax, and the like),” “What is the main navigation area?,” “How much propulsion power should the main engine have?,” and “There are ballast-system and fuel-tank arrangement types A, B, and C. Which type shall we refer to?” When the questions are generated, the processor 130 may sequentially provide the generated questions to the user through the user terminal 200.

The operation S130 of deriving the ship design information may include determining the user’s intent based on answers to questions received from the user terminal 200 and reflecting the user’s intent in the ship design information. Specifically, the ship design information may be updated in real time based on the ship design variables included in the answers.

When the user answers the above-described questions as “Please make the size Suezmax class,” “It is scheduled to operate mainly on an Asia–Europe route,” “I think propulsion power of about 100,000 horsepower will be sufficient,” and “Please refer to type B for the ballast system and fuel-tank arrangement,” the processor 130 may analyze the user’s answers in real time to extract the ship design variables. For example, the processor 130 may extract the ship size information “Suezmax class” from the first answer and extract navigation area information “Asia–Europe route” from the second answer. The extracted ship design variables may be organized in the form of a table 301 and output on the interface I so that the user can check the ship design variables.

The processor 130 may generate the ship design information by utilizing the ship design knowledge information based on the extracted ship design variables. For example, the processor 130 may calculate the length, breadth, draft, weight, and the like of the ship to design a basic shape of the ship, based on the information on “Suezmax class” and “Asia–Europe route.”

The processor 130 may provide the ship design information such as a generated three-dimensional (3D) model 303 of the ship, basic design drawings, and an estimated ship design cost 302 to the user in real time.

In one embodiment, the processor 130 may predict a target ship that the user ultimately desires to design, and generate questions for concretizing this.

When the user presets a requirement that “I want high speed,” the processor 130 may analyze the user’s requirement, that is, “I want high speed,” and predict a target design ship as a “high-speed container ship.” The processor 130 may ascertain design variables required for design of the high-speed container ship by using the ship design knowledge information. Examples of the design variables required for design of the high-speed container ship may include a hull form, engine power, a propulsion system, and a hull material. Based on the design variables ascertained by using the conversational artificial intelligence model 111, the processor 130 may generate specific questions for the user, such as “What is the desired maximum speed?” “What type of hull form do you prefer to reduce hull resistance (for example, a bulbous hull form or a V-type hull form)?” and “What type of fuel do you plan to use for a high output engine (for example, LNG or low-sulfur oil)?”

The processor 130 may concretize the target design ship based on the user’s answers to the questions. For example, when the user selects “maximum speed of 30 knots,” “bulbous hull form,” and “LNG fuel,” the processor 130 may reflect the ship design variables in the ship design information, update the 3D model 303 of the ship, design drawings, the estimated ship design cost 302, and the like based on the ship design information, and provide these to the user.

The automatic ship design system and method using the conversational artificial intelligence model of the present invention allow the user to design a desired ship by interacting with the system using everyday language instead of handling complicated design software. This allows even users lacking specialized knowledge to easily participate in ship design, and makes it possible to improve understanding of a design process by providing necessary information step by step under the guidance of the system.

Further, an automated design process makes it possible to shorten a design time, reduce design costs, and improve productivity.

The various embodiments described in the present disclosure may be implemented by hardware, middleware, microcode, software, and/or combinations thereof. For example, various embodiments may be implemented within one or more application-specific integrated circuits (ASICs), digital signal processors (DSPs), digital signal processing devices (DSPDs), programmable logic devices (PLDs), field programmable gate arrays (FPGAs), processors 130, controllers, microcontrollers, microprocessors 130, other electronic units designed to perform the functions presented herein, or combinations thereof.

Such hardware and the like may be implemented within the same device or in separate devices to support various operations and functions described in the present disclosure. Additionally, the components, units, modules, elements, and the like described as “unit” in the present invention may be implemented collectively or as individual but interoperable logic devices. Descriptions of different features of modules, units, and the like are intended to emphasize different functional embodiments and do not necessarily mean that the modules, units, and the like need to be realized by separate hardware components. Rather, functions associated with one or more modules or units may be performed by separate hardware components or integrated within common or separate hardware components.

With the automatic ship design system and method using a conversational artificial intelligence model according to the aspect of the present invention, it is possible to improve the efficiency of ship design work by receiving design variables of a ship using a conversational artificial intelligence model and deriving ship design information reflecting the received design variables in real time.

It is also possible to automatically derive a design plan of a target design ship that is a user’s conversational intent by predicting the target design ship and generating questions regarding related design variables step by step and asking the questions to the user to complete the target design ship, and to enable even a technician lacking expertise to easily obtain a high-quality design result.

It is also possible to increase user convenience so that anyone can easily perform ship design through the conversational interface and to perform the design intuitively.

The effects of the present invention are not limited to the content mentioned above, and other effects that are not mentioned will be clearly understood by those of ordinary skill in the art from the following description.

Although the present invention has been described with reference to the embodiments shown in the drawings, these are merely exemplary, and it will be understood by those of ordinary skill in the art that various modifications and equivalent other embodiments are possible therefrom. Accordingly, the true technical protection scope of the present invention should be determined by the technical spirit of the appended claims.

What is claimed is:

1. An automatic ship design system using a conversational artificial intelligence model, the automatic ship design system comprising:
a memory in which one or more instructions, ship design knowledge information, and the conversational artificial intelligence model are stored;
a communication unit for communication with a user terminal; and
a processor configured to communicate with the user terminal via the communication unit and execute the one or more instructions stored in the memory,
wherein the processor is configured to
perform a conversation with a user through the user terminal by using the conversational artificial intelligence model,
receive ship design variables through the conversation, and
derive ship design information in real time using the ship design knowledge information according to the received ship design variables.

2. The automatic ship design system using a conversational artificial intelligence model of claim 1, wherein the ship design knowledge information includes one or more of ship design requirement information, ship type and ship size information, definition information of a design stage, and boundary range information of the design stage.

3. The automatic ship design system using a conversational artificial intelligence model of claim 1, wherein the ship design information includes one or more of ship shape information, ship design drawings, and an estimated ship design cost.

4. The automatic ship design system using a conversational artificial intelligence model of claim 1, wherein the processor sequentially generates questions for ascertaining the user’s intent based on the ship design knowledge information by using the conversational artificial intelligence model, and sequentially provides the generated questions to the user through the user terminal.

5. The automatic ship design system using a conversational artificial intelligence model of claim 4, wherein the processor sequentially receives answers to the questions from the user terminal and determines the user’s intent based on the received answers to reflect the user’s intent in the ship design information.

6. The automatic ship design system using a conversational artificial intelligence model of claim 5, wherein the processor updates the ship design information in real time based on the ship design variables included in the answers.

7. The automatic ship design system using a conversational artificial intelligence model of claim 4,
wherein the user’s intent is a target design ship that the user desires to design, and
the processor predicts the target design ship and sequentially generates questions for the ship design variables for specifically designing the predicted target design ship.

8. A method performed by a processor of an automatic ship design system using a conversational artificial intelligence model, the method comprising:
performing a conversation with a user through a user terminal using the conversational artificial intelligence model;
receiving ship design variables through the conversation; and
deriving ship design information in real time using the ship design knowledge information according to the received ship design variables.

9. The method of claim 8, wherein the performing of the conversation with the user through the user terminal includes:
sequentially generating questions for ascertaining the user’s intent based on the ship design knowledge information by using the conversational artificial intelligence model, and
sequentially providing the generated questions to the user through the user terminal.

10. The method of claim 9, wherein the deriving of the ship design information includes determining the user’s intent based on answers to the questions received from the user terminal and reflecting the user’s intent in the ship design information.

11. The method of claim 10, wherein the deriving of the ship design information includes updating the ship design information in real time based on the ship design variables included in the answers.

12. The method of claim 9,
wherein the user’s intent is a target design ship that the user desires to design, and
the sequential generating of the questions includes predicting the target design ship and sequentially generating questions for the ship design variables for specifically designing the predicted target design ship.
